(19) United States
(12) Patent Application Publication
(10) Pub. No.: US 2009/0212794 A1
(43) Pub. Date: Aug. 27, 2009

(54) TEST KEY FOR SEMICONDUCTOR STRUCTURE

(75) Inventors: Chung-I Chang, Hsinchu City (TW); Hui-An Chang, Hsinchu City (TW); Neng-Cheng Wang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: PROMOS TECHNOLOGIES INC., Hsinchu (TW)

(21) Appl. No.: 12/190,565

(22) Filed: Aug. 12, 2008

(30) Foreign Application Priority Data
Feb. 22, 2008 (TW) 97106237

(51) Int. Cl. G01R 31/305

(52) U.S. Cl. 324/751

(57) ABSTRACT

A test key for a semiconductor structure is provided for in-line defecting defects of the contact. The test key is disposed on a scribe line of a wafer substrate, and includes conductive structures and contacts under test. The conductive structures are electrically connected with the substrate and the contacts under test are not electrically connected with the substrate. The conductive structures and the contacts under test are regularly arranged in array. When an electronic beam is utilized to perform in-line monitoring, the normal contacts under test will be shown as bright dots and the bright dots are regularly arranged in the array; any contact under test with defect will be shown as a dark dot which results in an irregular arrangement of the bright dots.

### CROSS-REFERENCE TO RELATED APPLICATION

This application claims the priority benefit of Taiwan application serial no. 97106237, filed on Feb. 22, 2008. The entirety of the above-mentioned patent application is hereby incorporated by reference herein and made a part of specification.

### BACKGROUND

1. Technical Field

The present invention relates to an integrated circuit structure and a monitoring method, and more particularly, to a test key for a semiconductor structure and a method for in-line monitoring a semiconductor structure.

2. Description of Related Art

With development of technology, semiconductor fabrication has become one of the most important industries. However, to meet different needs, the semiconductor fabrication process has become more and more complex. As a result, it is increasingly difficult to fabricate chips with high yield and at low cost.

In general, the fabrication process of semiconductor chips, starting from wafer to chip, may often involve several hundreds of process steps. It is generally impossible to know the performance of the whole process capability by merely testing the finished products prior to packing. Therefore, if information about performance of the process capability can be timely obtained during the fabrication process, it would be possible to determine the process status and timely take improvement measures or discard the chips under poor processing, as well as effectively reduce the fabrication cost and time.

In order to obtain the information about the performance of the process capability during the fabrication process, a plurality of test keys is dedicatedly disposed around the semiconductor die to detect unforeseeable errors during the process and monitor the performance of various stages of the process.

However, many defects may occur in the interconnection process that can not be detected with existing methods. For example, voids may be generated in the dielectric material or isolation material, which causes short-circuit at a bottom of a contact. It can be very difficult to monitor this void-type defect by using traditional test keys. In addition, short-circuit may occur between the gate and the contacts of the source/drain due to the defects of the mask on top of the gate, which will decrease the yield of the fabrication process. In addition, since the current monitoring method is performed in an off-line manner, i.e., the products must be removed out of the production line for testing, and will increase the fabrication time and hence the fabrication cost.

### SUMMARY

The present invention is directed to a test key for a semiconductor structure that uses insulated contacts and grounded contacts as the test key to timely in-line monitor defects in the semiconductor structure.

The present invention is also directed to a test key for a semiconductor structure that includes contacts disposed between gates and uses insulated contacts and contacts connected with a substrate to timely in-line monitor defects in the semiconductor structure.

The present invention is further directed to a test key for a semiconductor structure including an arrangement such that the contact connected to the substrate is electrically conducted with two adjacent gates and the insulated contact is adjacent to at least one of the two adjacent gates to thereby facilitate real time in-line monitoring detection in the semiconductor structure.

The present invention provides a method for in-line monitoring a semiconductor structure that can in-line detect a defect location by using an arrangement of the test key.

The present invention provides a test key for a semiconductor structure for in-line monitoring a defective contact. The test key is disposed on a scribe line of a wafer. The test key includes a plurality of conductive structures and a plurality of contacts under test. The conductive structures are electrically conducted with the substrate. The contacts under test are electrically insulative from the substrate. The conductive structures and the contacts under test are regularly arranged in an array. When an electron beam is employed to perform in-line monitoring, the contacts, if normal, are shown as bright dots and the bright dots are regularly arranged in an array; while the defective contacts, if any, are shown as dark dots resulting in an irregular arrangement of the bright dots in the array.

The present invention provides a test key for a semiconductor structure including a substrate and a dielectric. The test key includes a plurality of first contacts and a plurality of second contacts. The first contacts are disposed in the dielectric layer and electrically conducted with the substrate. The second contacts are disposed in the dielectric layer and electrically isolated from the substrate. If the semiconductor device is defective, at least one of the second contacts is electrically connected with one first contact, such that the defect can be in-line monitored.

The present invention provides a method for in-line monitoring a semiconductor structure including a dielectric layer. A test key is first formed in a dielectric layer. The test key at least includes a first contact with a grounded bottom end and a second contact with an insulated bottom end. An electron beam is directed toward the first contact and the second contact to generate a plurality of electronic signals. The electronic signals are then analyzed to in-line monitor the semiconductor structure. The electronic signal generated by the first contact and the electronic signal generated by the second contact are different in intensity. However, if the semiconductor structure is defective, the second contact is conductive with the first contact such that the second contact generates an electronic signal with the same intensity as the first contact.

In the present invention, the insulated contacts and the grounded contacts are arranged to form a unique test key. With this arrangement, the test key can in-line monitor the semiconductor structure and easily determine the location of the defect, especially the defect in the dielectric layer. As such, the fabrication process time can be significantly reduced. Moreover, this can determine the location of the defect and timely modify the process parameters, thereby increasing the yield of the subsequent wafer fabrication processes.

In order to make the aforementioned and other features and advantages of the present invention more comprehensible, embodiments accompanied with figures are described in detail below.

### BRIEF DESCRIPTION OF THE DRAWINGS

FIG. 1A is a top view of a test key for a semiconductor structure according to one embodiment of the present invention.

FIG. 1B is a cross-sectional view of FIG. 1A, taken along line I-I′ thereof.

FIG. 1C is a schematic view illustrating a method for monitoring a semiconductor structure using the test key of FIG. 1A.

FIG. 2A is a top view of a test key for a semiconductor structure according to another embodiment of the present invention.

FIG. 2B is a cross-sectional view of FIG. 2A, taken along line I-I′ thereof.

FIG. 2C is a schematic view illustrating a method for monitoring a semiconductor structure using the test key of FIG. 2A.

FIG. 2D is a top view of a test key for a semiconductor structure according to another embodiment of the present invention.

FIG. 3A is a top view of a test key for a semiconductor structure according to yet another embodiment of the present invention.

FIG. 3B is a cross-sectional view of FIG. 3A, taken along line I-I′ thereof.

FIG. 3C is a cross-sectional view of FIG. 3A, taken along line II-II′ thereof.

FIG. 3D is a schematic view illustrating a method for monitoring a semiconductor structure using the test key of FIG. 3A.

FIG. 3E is a cross-sectional view of FIG. 3D, taken along line II-II′ thereof.

### DESCRIPTION OF THE EMBODIMENTS

The invention will now be described more fully with reference to the accompanying drawings, in which exemplary embodiments of the invention are shown. The invention may, however, be embodied in other forms and should not be construed as being limited to the embodiments set forth herein. In the drawings, the dimension of layers and regions are exaggerated for clarity.

In addition, terms in the description are used for the purpose of describing the applicable embodiments and should not be used to limit the present invention. The two objects in such relationship are not necessarily electrically conducted with each other, and whether they are conductive with each other will be determined depending upon the relevant description.

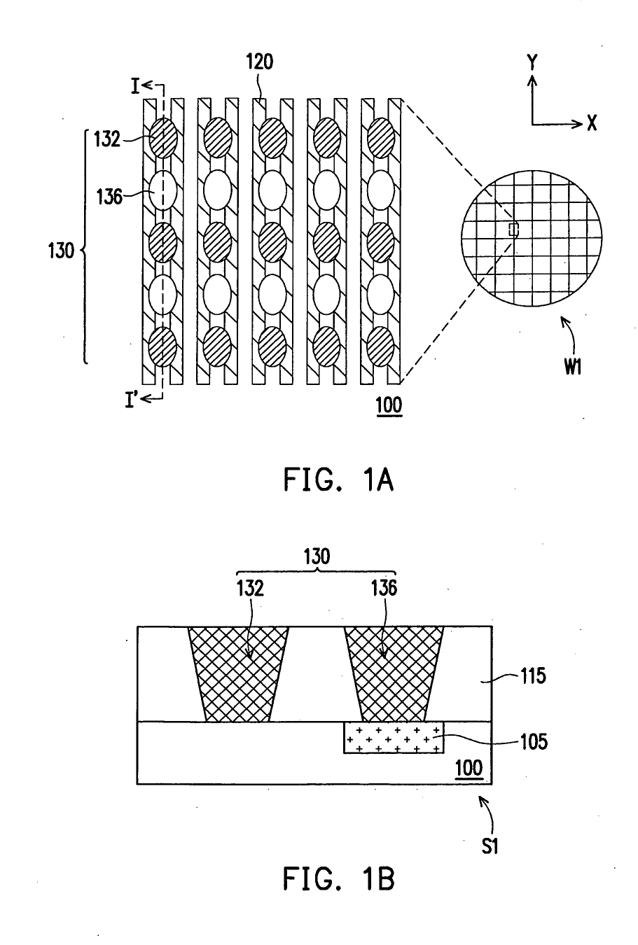

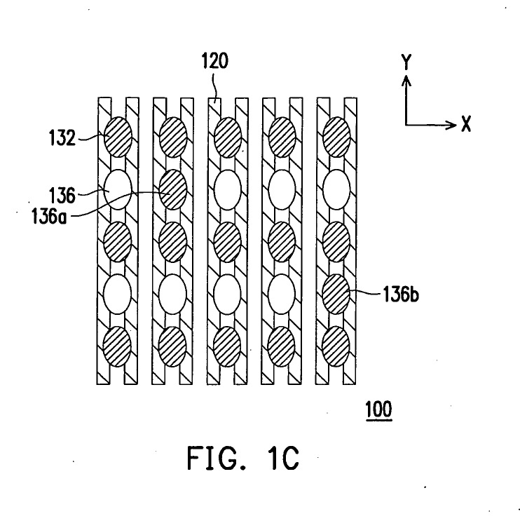

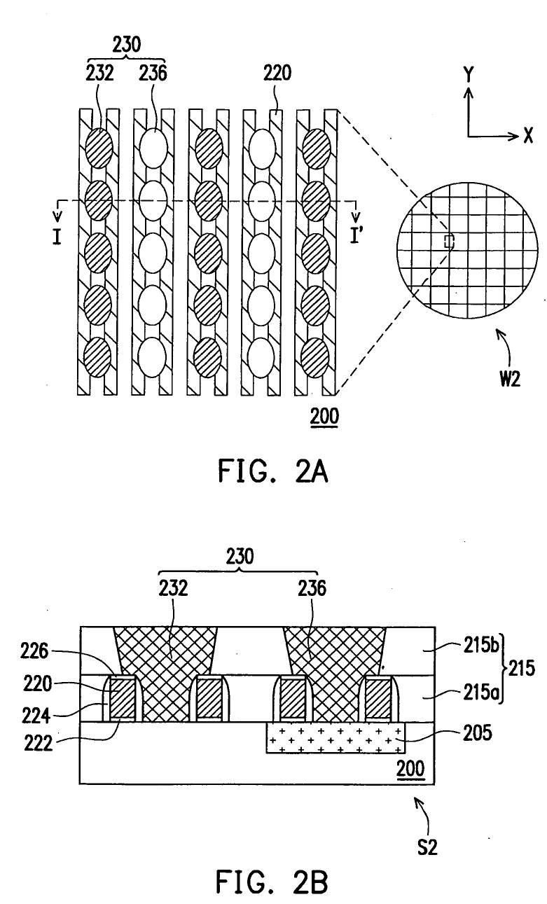

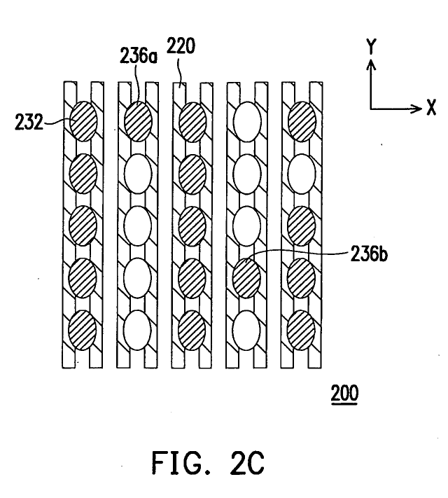

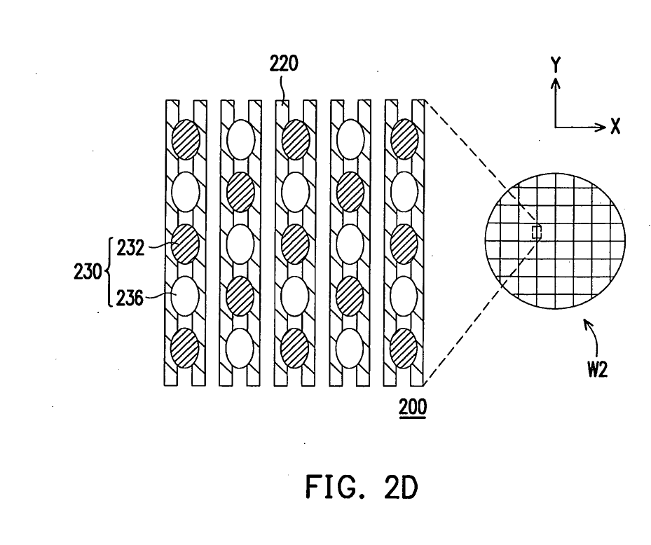

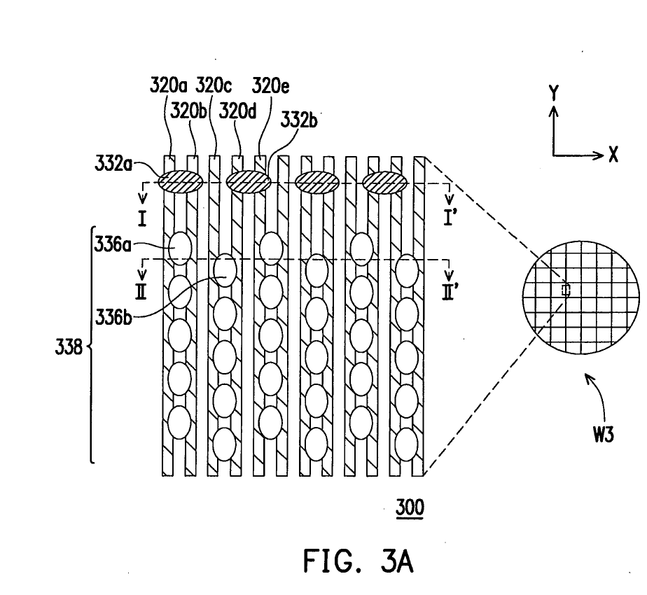

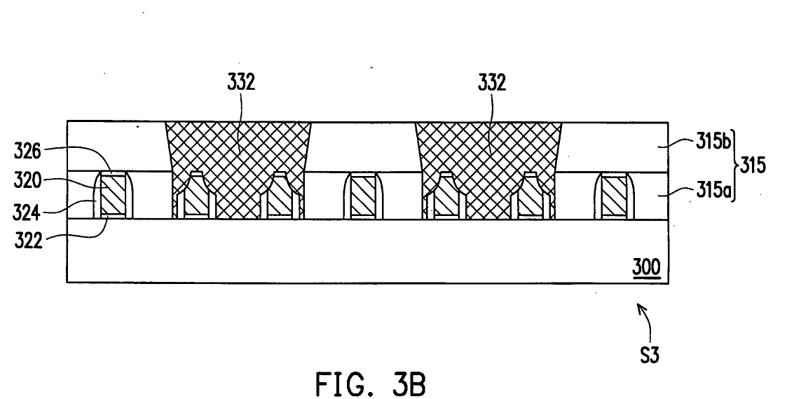

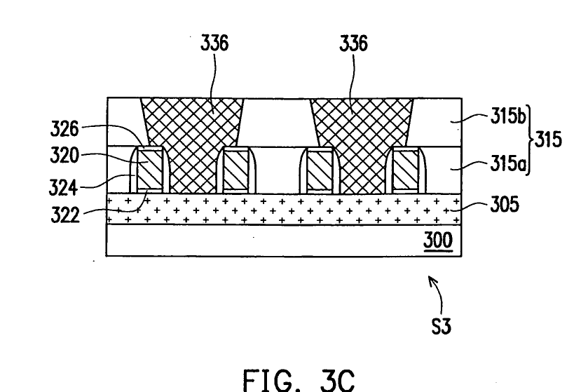

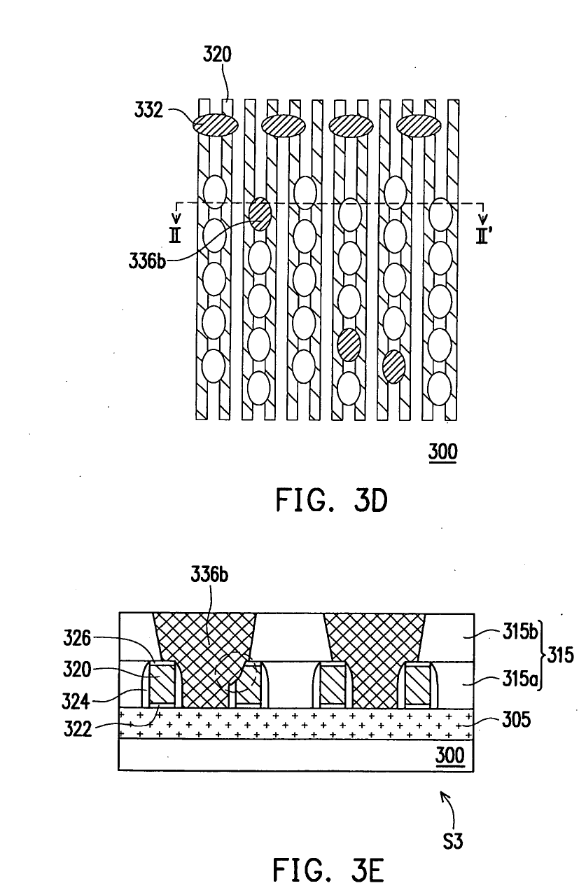

FIG. 1A is a top view of a test key for a semiconductor structure according to one embodiment of the present invention. FIG. 1B is a cross-sectional view of FIG. 1A, taken along line I-I′ thereof. FIG. 2C is a schematic view illustrating a method for testing a semiconductor structure including the test key of FIG. 2A. FIG. 3A is a top view of a test key for a semiconductor structure according to another embodiment of the present invention. FIG. 3B is a cross-sectional view of FIG. 3A, taken along line I-I′ thereof.

Referring to FIGS. 1A and 1B, in the present embodiment, the semiconductor structure S1 includes a substrate 100 and a dielectric layer 115, for example. The substrate 100 is, for example, a semiconductor substrate, a III-V compound substrate, or a silicon-on-insulator (SOI) substrate. The substrate 100, for example, includes an isolation structure 105 which may be a shallow trench structure or a field oxide. The material of the dielectric layer 115 may be, for example, selected from a group consisting of dielectric materials, such as, silicon oxide, silicon nitride, silicon oxynitride, silicon dioxide formed using tetraethylorthosilicate (TEOS) as a reactive gas source, borophosphosilicate glass (BPSG), borosilicate glass (PSG). In addition, a plurality of gates 120, which may be, for example, elongated in shape, is formed on the substrate 100. These gates 120 extend in a Y direction and are arranged in parallel with each other in an X direction. The material of the gates 120 is, for example, a conductive material, such as, doped polysilicon, metal or metal silicide.

The test key 130 includes a contact 132 and a contact 136 formed in the dielectric layer 115, for example. A bottom end of the contact 132 is grounded and, for example, is connected with the substrate 100. The bottom end of the contact 136 is insulated and, for example, is isolated from the substrate 100 with the isolation structure 105. The contact 132 and contact 136 are formed, for example, between two gates 120, as illustrated in FIG. 1A. The material of the contacts 132, 136 may be, for example, doped polysilicon, metal or metal silicide. Any defects in the semiconductor structure SI can result in electrical conduction between the contact 136 and the contact 132, such that the defect can be in-line monitored. The method for in-line monitoring will be described later in greater detail.

Referring to FIG. 1A, the test key 130 may further include a plurality of contacts 132 and contacts 136 arranged in array. The contacts 132 and the contacts 136 are arranged in rows along the X direction, with each row of the contacts 132 being arranged alternately with each row of the contacts 136. In addition, the test key 130 may be, for example, disposed on a scribe line of a wafer, which reduce space occupation area on the wafer.

When the test key of this exemplary embodiment is used to perform in-line monitoring of the semiconductor structure S1, the method is carried out, for example, by employing an electron beam directed to the contacts 132 and contacts 136 to generate a plurality of electronic signals. If the semiconductor structure S1 is normal and non defects, the amount of secondary electrons produced by the contacts 136 will be more than that produced by the contacts 132 conductive with the substrate 100, i.e., the intensity of the electronic signals on the surface of the contacts 136 will be stronger than that on the surface of the contacts 132. As shown in FIG. 1A, it can be observed by using an image processing system that it is shown as bright dots at the locations of insulated contacts 136 while it is shown as relatively dark dots at the locations of the grounded contacts 132.

If the dielectric layer 115 disposed between the contact 132 and the contact 136 is defective, it will result in conduction between the contact 136 and the contact 132, so that the intensity of the electronic signal produced on the surface of the contact 136 will be generally the same as that produced on the surface of the contact 132, as illustrated in FIG. 1C. After image processing, it can be observed that it is shown as dark dots at the locations of the contacts 136a, 136b where should have been shown as bright dots. This way, the defective locations can easily be detected during the fabrication process, and parameters of the process can thus be timely modified to increase the fabrication yield of the wafer.

It will be appreciated from the above description of the monitoring method, the arrangement of the contacts in the test key is not limited to the above embodiment; rather, the contacts can be regularly arranged in such a manner that one of two adjacent contacts is insulated (bright dots) while the other is electrically conducted with the substrate (dark dots). As such, once a defect exists in the semiconductor structure and the contact that should have been shown as a bright dot is shown as a dark dot, the location of the defect can easily be identified.

In addition to the arrangement in the X direction, the contacts may alternately be arranged in the Y direction. Referring to FIGS. 2A and 2B, in another embodiment of the present invention, the semiconductor structure S2 includes, for example, a substrate 200, a dielectric layer 215 and a plurality of gates 220. Each gate 220 is formed on the substrate 200 and separated from the substrate 200 with a gate dielectric 222. The material of the gate 220 includes, for example, doped polysilicon, metal or metal silicide. The material of the gate dielectric 222 includes, for example, silicon oxide. A protective layer 226 may be disposed on each gate 220, and a spacer 224 may be disposed at two sides of each gate 220. The material of the protective layer 226 includes, for example, a dielectric material such as silicon nitride, silicon oxynitride, silicon carbide or silicon carbide nitride. The material of the spacer 224 may be silicon oxide or silicon nitride. The dielectric layer 215 includes, for example, an interlayer dielectric disposed on the substrate 200 to cover the gates 220. The material of the dielectric layer 215 includes, for example, at least one of silicon nitride, silicon oxide and silicon oxynitride, or another suitable dielectric material. The siliconoxide is, for example, formed using tetraethylorthosilicate (TEOS) as a reactive gas source, borophospho silicon oxide, borophosphosilicate glass (BPSG), or borosilicate glass (PSG). The dielectric layer 215 may be formed by chemical vapour deposition or spin coating depending on the material of the dielectric layer 215. In one embodiment, the dielectric layer 215 may be comprised of a bottom dielectric layer 215a of BPSG and a top dielectric layer 215b of TEOS.

Referring to FIG. 2B, the test key consists of adjacent contact 232 and contact 236, for example. The contact 232 and contact 236 are disposed between two adjacent gates 220, respectively. The contact 232 extends through the dielectric layer 215 and is connected to the substrate 200, while the contact 236 is insulated from the substrate 200 by an isolation structure 205.

Referring to FIG. 2A, in one embodiment, the test key 230 may include a plurality of contacts 232 and a plurality of contacts 236. The contacts 232 and the contacts 236 are arranged in rows in the Y direction, respectively, with each row of contacts 232 being alternately arranged with each row of contacts 236. The test key 230 is, for example, disposed on the scribe line of a wafer W2.

When the test key of this exemplary embodiment is used to perform in-line monitoring of the semiconductor structure S2, the method is carried out, for example, by providing an electron beam directed to the contacts 232 and contacts 236 to generate a plurality of electronic signals. If the semiconductor structure S2 has no defects, as shown in FIG. 2A, it is shown as dark dots at the locations of the grounded contacts 232 while it is shown as bright dots at the locations of the insulated contacts 236. If the semiconductor structure S2 is defective, particularly, if the dielectric layer 215 disposed between the contact 232 and the contact 236 has a void-type defect, it will result in conduction between the two contacts, so that, as illustrated in FIG. 2C, it is shown as dark dots at the locations of the contacts 236a, 236b where should have been shown as bright dots. By observing these contacts 236a, 236b shown as dark dots, the locations of the defects can be detected timely without removing the semiconductor structure S2 out of the production line for testing. This not only reduces the fabrication time, but also allows the process parameters to be timely modified to increase the fabrication yield of the wafer.

In addition to the two arrangements described above, the contacts can also be alternately arranged in a checkered arrangement, as illustrated in FIG. 2D. Like reference numerals of FIG. 2D refer to like elements in FIG. 2A. The material of the elements and monitoring method are similar to those described above.

Referring to FIG. 3C, in another embodiment of the present invention, the semiconductor structure S3 includes, for example, a substrate 300, a dielectric layer 315 and a plurality of gates 320. The dielectric layer 315 is, for example, an interlayer dielectric. The dielectric layer 315 may alternatively consist of a bottom dielectric 315a and a top dielectric 315b. A gate dielectric 322 is disposed between each gate 320 and the substrate 300. A protective layer 326 is disposed above each gate 320. A spacer 324 may also be disposed at two sides of each gate 320. The material of elements of the semiconductor structure S3 may be similar to those described above and, therefore, is not repeated.

Referring to FIG. 3A which is a top view of a test key according to another embodiment, this test key is comprised of a contact 332 and a contact 336. Gates 320 are elongated in shape and arranged in parallel with each other. A plurality of contacts 336 is arranged in an array 338, and FIG. 3C illustrates a cross-sectional view of the contacts 336. A plurality of contacts 332 is arranged along at least an outer side of the array 338, and FIG. 3B illustrates a cross-sectional view of the contacts 332. It should be noted that the relative position between the contacts 332 and the gates 320 are not limited to the arrangement shown in FIG. 3A. Rather, any relative positions are possible as long as the contacts 332 and the gates 320 are conductive with the substrate 300. In addition, the test key is, for example, disposed on a scribe line of a wafer W3.

As shown in FIG. 3B, the contact 332 is disposed in the dielectric layer 315, covering and electrically connected with two adjacent gates 320. In addition, the contact 332 extends through the dielectric layer 315 to connect to the substrate 300.

Referring to FIG. 3C, the contact 336 is disposed in the dielectric layer 315 and located between two adjacent gates 320. The contact 336 is positioned adjacent to at least one of the two adjacent gates 320 conductive with the contact 332. The contact 336 is insulated from the substrate 300 by an isolation structure 305 and is insulated from the gate by a protective layer 326 and a spacer 324. Referring to FIG. 3A, the contact 336a is, for example, disposed between the two adjacent gates 320a, 320b conductive with the contact 332a and is adjacent to the gates 320a, 320b. As to contact 336b, the contact 332b is conductive with two adjacent gates 320d, 320e, and the contact 336b is indeed positioned adjacent and conductive with the gate 320d.

Referring to FIG. 3A, in normal situation, since the contact 332 is grounded and the contact 336 is insulated, it will be shown as a bright dot at the location of the contact 336. However, if the semiconductor structure S3 is defective, for example, referring to FIG. 3E, if the protective layer 326 or the spacer 324 has a void, this will cause short-circuit between the contact 336b and the gate 320d. Because the gate 320d is conductive with the contact 332b, the contact 33 6b is also conductive with the contact 332b and is thus grounded. As a result, the contact 336b, where should have been shown as a bright dot, is shown as a dark dot, as illustrated in FIG. 3D. This way, the defect in the semiconductor structure S3 can be detected.

It is noted that, the test keys with various arrangements described above may be integrated onto the scribe line of a same wafer or even around a same die by controlling the fabrication process conditions, thereby more accurately monitoring the fabrication process of the semiconductor structure and increasing the yield of the wafer.

In summary, the insulated contact and grounded contact of the test key of the present invention are arranged adjacent to each other, such that whether the semiconductor structure, especially the dielectric layer of the semiconductor structure, is defective and the location of the defect can be determined. Therefore, the semiconductor structure fabrication process can be in-line monitored without removing the semiconductor structure out of the production line. As such, the present invention can reduce the time of the fabrication process and timely correct the fabrication process parameters as well, thereby increasing the yield. Moreover, the test key is disposed on the scribe line of the wafer and, therefore, the test key will not occupy the original room for chips, thereby facilitating element integration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A test key for a semiconductor structure for in-line monitoring, the test key being disposed on a scribe line of a substrate, and comprising:
a plurality of conductive structures electrically connected with the substrate; and
a plurality of contacts under test electrically isolated from the substrate;
wherein the conductive structures and the contacts under test are regularly arranged in an array, when an electron beam is employed to perform in-line monitoring, the contacts under test, if normal, are shown as bright dots and the bright dots are regularly arranged in the array; while defective contacts are shown as dark dots resulting in an irregular arrangement of the bright dots in the array.

2. The test key for the semiconductor structure in accordance with claim 1, wherein each of the contacts under test is disposed on an isolation structure.

3. The test key for the semiconductor structure in accordance with claim 1, wherein the conductive structures are contacts not under test.

4. The test key for the semiconductor structure in accordance with claim 1, wherein the defective contact is electrical bridging to an adjacent contact under test.

5. The test key for the semiconductor structure in accordance with claim 1, wherein each of the contacts under test with its adjacent gates are disposed on an isolation structure.

6. The test key for the semiconductor structure in accordance with claim 5, wherein the defective contact and an adjacent gate are conductively connected with each other.

7. The test key for the semiconductor structure in accordance with claim 1, wherein the contacts under test and the contacts not under test are arranged in rows, respectively, with the rows of the contacts under test and the contacts not under test being alternately arranged.

8. The test key for the semiconductor structure in accordance with claim 1, wherein the contacts under test and the contacts not under test are alternately arranged in a checkered arrangement.

9. The test key for the semiconductor structure in accordance with claim 1, wherein the conductive structure are gates, and the gates are electrically connected with the substrate in a predetermined way but non-electrically connected with the gates.

10. The test key for the semiconductor structure in accordance with claim 9, wherein the contacts under test are arranged in a row and in parallel with the gates.

11. A test key for a semiconductor structure used for in-line monitoring short between a contact and its adjacent gate, and comprising:
a substrate and a dielectric layer formed on the substrate;
a plurality of first contacts disposed in the dielectric layer and electrically conducted with the substrate; and
a plurality of second contacts disposed on a isolation structure, so as to be isolated from the substrate;
wherein the first contacts and the second contacts are disposed between and isolated from the gates via a spacer, respectively.

12. The test key for the semiconductor structure in accordance with claim 11, wherein the semiconductor structure comprises a plurality of gates disposed in the dielectric layer.

13. The test key for the semiconductor structure in accordance with claim 11, wherein the spacer is defective, the second contact is electrically connected with the first contact.

14. The test key for the semiconductor structure in accordance with claim 11, wherein each first contact is electrically connected with two adjacent gates, and each second contact is adjacent to at least one of the two adjacent gates.

15. The test key for the semiconductor structure in accordance with claim 11, wherein the second contacts are arranged in an array, and the first contacts are arranged along at least an outer side of the array.

16. The test key for the semiconductor structure in accordance with claim 11, wherein the test key is disposed on a scribe line of a wafer.
